(19) United States
(12) Patent Application Publication
(10) Pub. No.: US 2024/0260236 A1
(43) Pub. Date: Aug. 1, 2024

(54) ELECTRONIC DEVICE

(71) Applicant: Panasonic Intellectual Property Management Co., Ltd., Osaka (JP)

(72) Inventors: Munehiro TORII, Osaka (JP); Noriyuki MAKI, Osaka (JP); Shogo MIKAMI, Miyagi (JP); Yutaro USUGINU, Osaka (JP); Tatsuya TOBIMATSU, Osaka (JP)

(73) Assignee: Panasonic Intellectual Property Management Co., Ltd., Osaka (JP)

(21) Appl. No.: 18/629,721

(22) Filed: Apr. 8, 2024

Related U.S. Application Data
(63) Continuation of application No. PCT/JP22/36888, filed on Oct. 3, 2022.

(30) Foreign Application Priority Data
Oct. 27, 2021 (JP) 2021-175720

(51) Int. Cl. H05K 7/20; H05K 5/03

(52) U.S. Cl. CPC H05K 7/20472; H05K 5/03; H05K 7/20409

(57) ABSTRACT

An electronic device of the present disclosure includes a communication module that includes a communication function, and includes a first module surface and a second module surface opposed to the first module surface, a first heat dissipation material that is disposed on the first module surface, an input interface that is operated by a user, a housing that accommodates the communication module, and includes a first surface facing the first module surface and a second surface opposed to the first surface, the input interface being provided on the second surface. The first surface of the housing includes a first recess recessed toward the second surface, and the first recess includes a first wall coming into contact with the first heat dissipation material.

### BACKGROUND

### 1. Technical Field

The present disclosure relates to an electronic device.

### 2. Description of the Related Art

Patent Literature (PTL) 1 discloses a communication module including a heating element implemented on a circuit board and a heat dissipation member gripped between a housing and the heating element.

PTL 1 is Unexamined Japanese Patent Publication No. 2019-186375.

### SUMMARY

There is still room for improvement in the electronic device on which the communication module described in PTL 1 is mounted in terms of improvement in heat dissipation function.

The present disclosure provides an electronic device with an improved heat dissipation function.

An electronic device according to an aspect of the present disclosure includes a communication module that includes a communication function, and includes a first module surface and a second module surface opposed to the first module surface, a first heat dissipation material that is disposed on the first module surface, an input interface that is operated by a user, a housing that accommodates the communication module, and includes a first surface facing the first module surface and a second surface opposed to the first surface, the input interface being provided on the second surface. The first surface of the housing includes a first recess recessed toward the second surface, and the first recess includes a first wall coming into contact with the first heat dissipation material.

According to the present disclosure, an electronic device with an improved heat dissipation function can be provided.

### BRIEF DESCRIPTION OF THE DRAWINGS

FIG. 1 is a perspective view illustrating an example of an electronic device according to a first exemplary embodiment.

FIG. 2 is a diagram illustrating a second surface of a second housing of the electronic device of FIG. 1.

FIG. 3 is a diagram illustrating a first surface of the second housing of the electronic device of FIG. 1.

FIG. 4 is an exploded perspective view of FIG. 2.

FIG. 5 is a diagram illustrating disposition of a communication module.

FIG. 6A is a perspective view of the communication module.

FIG. 6B is a perspective view of the communication module.

FIG. 7A is a perspective cross-sectional view of the electronic device taken along line A-A illustrated in FIG. 4.

FIG. 7B is a perspective cross-sectional view of the electronic device taken along line B-B illustrated in FIG. 4.

FIG. 8A is an enlarged view of FIG. 3.

FIG. 8B is a cross-sectional view of a first recess taken along line C-C illustrated in FIG. 8A.

### DETAILED DESCRIPTION

### Background of Present Disclosure

In recent years, a communication module having a higher speed communication function is mounted on an electronic device. However, the amount of heat of such a communication module is larger than the amount of heat of a communication module of the related art. When the amount of heat of the communication module increases, heat is accumulated around the communication module, and a speed and quality of communication by the communication module may be deteriorated by the heat. Accordingly, in the electronic device, improvement of a heat dissipation function is required.

Therefore, in order to solve the above problems, the inventors of the present invention have found a configuration in which a recess is provided on a surface opposite to a surface on which an input interface is disposed in a housing of an electronic device and heat is dissipated through the recess, and have reached the present disclosure.

An electronic device according to a first aspect of the present disclosure includes a communication module that includes a communication function, and includes a first module surface and a second module surface opposed to the first module surface, a first heat dissipation material that is disposed on the first module surface, an input interface that is operated by a user, a housing that accommodates the communication module, and includes a first surface facing the first module surface and a second surface opposed to the first surface, the input interface being provided on the second surface. The first surface of the housing includes a first recess recessed toward the second surface, and the first recess includes a first wall coming into contact with the first heat dissipation material.

With such a configuration, an electronic device with an improved heat dissipation function can be provided.

In an electronic device according to a second aspect of the present disclosure, one or a plurality of fins rising in a thickness direction from the second surface toward the first surface are provided in the first recess.

With such a configuration, it is possible to provide an electronic device with a further improved heat dissipation function by providing the fins.

In an electronic device according to a third aspect of the present disclosure, the first wall includes a bottom extending in a direction orthogonal to the thickness direction, the bottom comes into contact with the first heat dissipation material, and the one or plurality of fins rise in the thickness direction from the bottom.

With such a configuration, the first heat dissipation material and the fins are close to each other, and thus, it is possible to provide an electronic device with a further improved heat dissipation function.

In an electronic device according to a fourth aspect of the present disclosure, the first recess is formed in a rectangular shape as viewed in the thickness direction, the first wall includes two side walls that extend along the thickness direction and are opposed to each other, and the plurality of fins are provided in the first recess to extend in parallel with each other between the two side walls.

With such a configuration, it is possible to provide an electronic device with a further improved heat dissipation function by increasing a surface area of the fin.

In an electronic device according to a fifth aspect of the present disclosure, the plurality of fins are provided at equal intervals.

With such a configuration, since air easily enters around the fins, heat exchange between the fins and the air is promoted, and it is possible to provide an electronic device with a further improved heat dissipation function.

An electronic device according to a sixth aspect of the present disclosure further includes a second heat dissipation material that is disposed on the second module surface. A second recess recessed toward the first surface is formed in the second surface of the housing, and the second recess is formed by a second wall coming into contact with the second heat dissipation material.

With such a configuration, it is possible to provide an electronic device with a further improved heat dissipation function by forming the recesses on both surfaces of the housing.

In an electronic device according to a seventh aspect of the present disclosure, the second recess, the communication module, and the first recess are disposed to be lined up in the thickness direction from the second surface toward the first surface.

With such a configuration, it is possible to provide an electronic device with a further improved heat dissipation function by forming the recesses on both sides of the communication module.

In an electronic device according to an eighth aspect of the present disclosure, the communication module includes a controller, and the second recess, the controller, and the first recess are lined up in the thickness direction.

With such a configuration, it is possible to provide an electronic device with a further improved heat dissipation function by forming the recesses on both sides of the controller that generates heat.

In an electronic device according to a ninth aspect of the present disclosure, the second recess is covered with the input interface.

With such a configuration, the disposition of the input interface can suppress direct transfer of the heat dissipated from the communication module through the second recess to the user of the electronic device.

An electronic device according to a tenth aspect of the present disclosure further include a lid that covers the second recess.

With such a configuration, water or the like flowing between the housing and the input interface is prevented from flowing into the second recess.

Hereinafter, an exemplary embodiment of the present disclosure will be described with reference to the accompanying drawings. In addition, in each drawing, each element is exaggerated in order to facilitate the description.

In this specification, the terms “first”, “second”, and the like are only used for description, and should not be understood as explicitly or implying relative importance or a rank of a technical feature. Features limited to “first” and “second” are intended to imply the inclusion of one or more such features.

### First Exemplary Embodiment

### [Overall Configuration of Electronic Device]

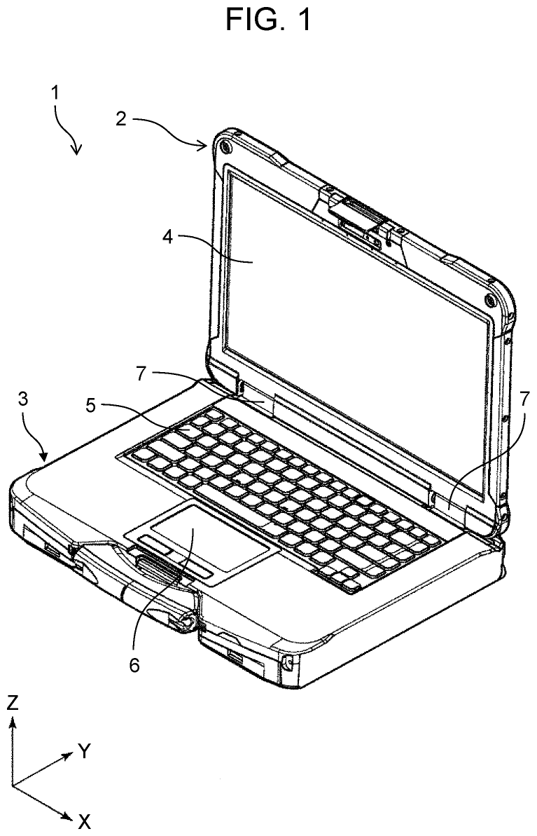

FIG. 1 is a schematic perspective view of an example of electronic device 1 according to a first exemplary embodiment of the present disclosure. Note that, X-, Y-, and Z-directions in the drawing indicate a width direction, a depth direction, and a thickness direction of electronic device 1, respectively.

As illustrated in FIG. 1, electronic device 1 is a notebook personal computer (laptop PC). Electronic device 1 includes first housing 2 and second housing 3. Each of first housing 2 and second housing 3 has a thin box-shaped outer contour and has a rectangular shape.

First housing 2 houses display 4. Display 4 is, for example, a liquid crystal. A display surface of display 4 is exposed from first housing 2. In addition, first housing 2 also houses an array microphone, an imaging unit, an antenna, and the like.

Second housing 3 houses an input interface. The input interface is, for example, keyboard 5 and touch pad 6. The input interface is exposed from second housing 3. Note that, in the present specification, keyboard 5 and touch pad 6 may be referred to as input interfaces 5 and 6. In addition, circuits such as a CPU and a memory, a battery, and the like are housed inside second housing 3.

First housing 2 and second housing 3 are connected via hinge 7. Hinge 7 rotatably connects first housing 2 and second housing 3. Hinge 7 allows first housing 2 and/or second housing 3 to rotate and bring electronic device 1 into an open state or a closed state. Note that, the “open state” means a state where first housing 2 and second housing 3 are away from each other and display 4 and input interfaces 5 and 6 are exposed. The “closed state” means a state where first housing 2 and second housing 3 are disposed to be opposed to each other, display 4 and input interfaces 5 and 6 face each other, and display 4 and input interfaces 5 and 6 are not exposed.

First housing 2 and second housing 3 are made of a metal material. For example, first housing 2 and second housing 3 are made of a magnesium alloy. A thickness of the magnesium alloy forming first housing 2 and second housing 3 is, for example, from 1.2 mm to 1.5 mm inclusive.

### [Housing]

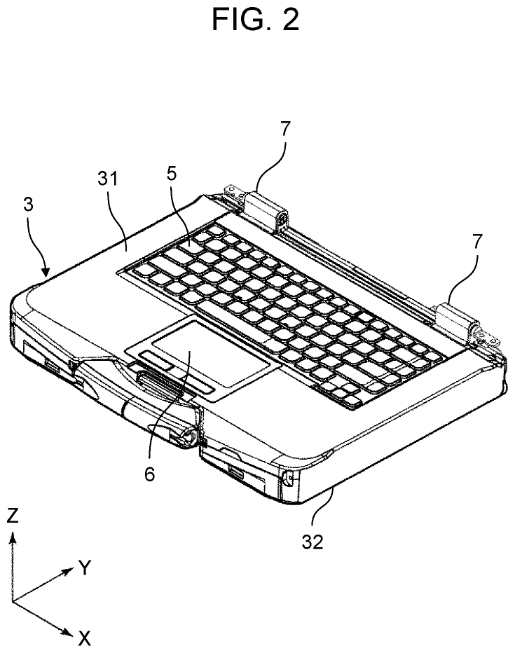

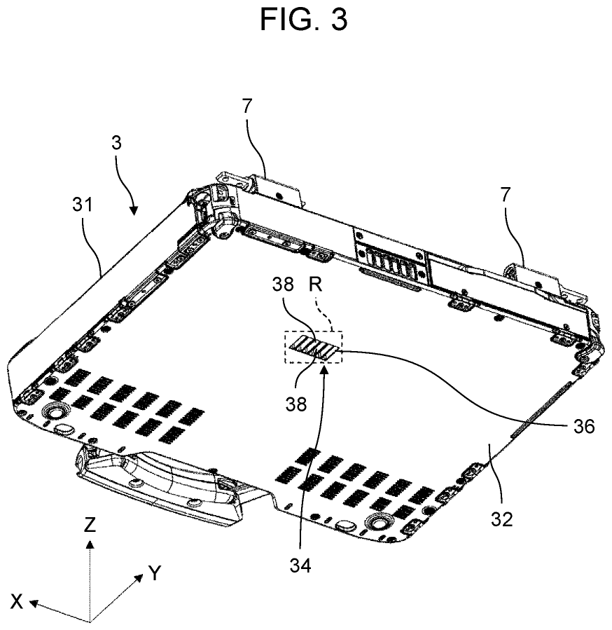

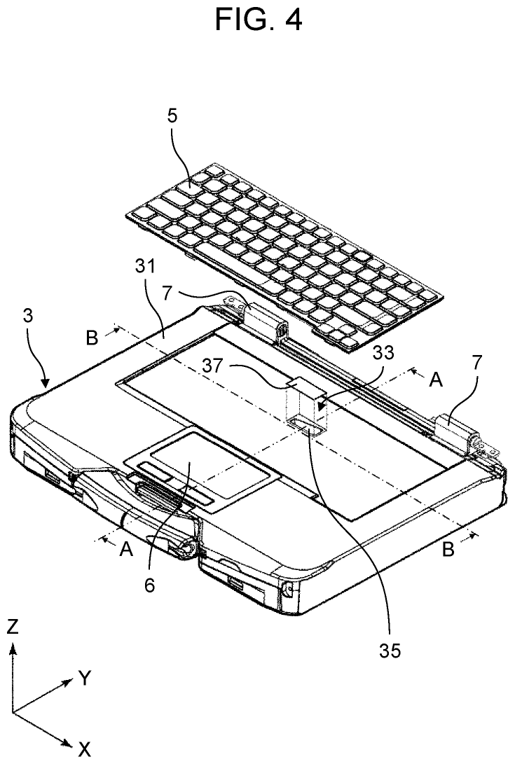

Here, second housing 3 will be described in more detail with reference to FIGS. 2 to 4. FIG. 2 is a diagram illustrating a second surface of second housing 3 of electronic device 1. FIG. 3 is a diagram illustrating a first surface of second housing 3 of electronic device 1. FIG. 4 is an exploded perspective view of FIG. 2.

As illustrated in FIGS. 2 and 3, second housing 3 has first surface 32 and second surface 31. In the present exemplary embodiment, first surface 32 corresponds to a lower surface, and second surface 31 corresponds to an upper surface. First surface 32 and second surface 31 are opposed to each other and are lined up in thickness direction Z. As illustrated in FIG. 2, second surface 31 is a surface on which keyboard 5 is disposed. As illustrated in FIG. 3, first surface 32 is a surface opposite to first surface 32, and may be a surface on which a user of electronic device 1 hardly touches with hand at the time of using electronic device 1. First surface 32 is, for example, a surface placed on a top plate such as a table, a counter, or a workbench when electronic device 1 is used.

First surface 32 and second surface 31 are exposed to an outside air. First surface 32 may be exposed to the outside air to directly contact the outside air. First surface 32 is exposed to the outside air on, for example, the entire surface. Second surface 31 may form a gap into which the outside air can flow between the second surface and keyboard 5.

As illustrated in FIG. 3, first recess 34 recessed toward second surface 31 is formed in first surface 32. First recess 34 is formed by first wall 36 recessed from first surface 32 toward second surface 31. First recess 34 has a plurality of fins 38 rising in thickness direction Z. Fin 38 is a thin plate-shaped member. Fin 38 is made of metal. For example, fin 38 is made of a magnesium alloy.

As illustrated in FIG. 4, second recess 33 recessed toward first surface 32 is formed on second surface 31 on which keyboard 5 is disposed. Second recess 33 is formed by second wall 35 recessed from second surface 31 toward first surface 32. Second recess 33 is covered with lid 37. Second recess 33 may be sealed by lid 37. As illustrated in FIG. 4, lid 37 is covered with keyboard 5.

As viewed in thickness direction Z, first recess 34 and second recess 33 may have a polygonal shape. First recess 34 has, for example, a rectangular shape. Second recess 33 has, for example, a trapezoidal shape.

Detailed structures of first recess 34 and second recess 33 will be described later.

### [Communication Module]

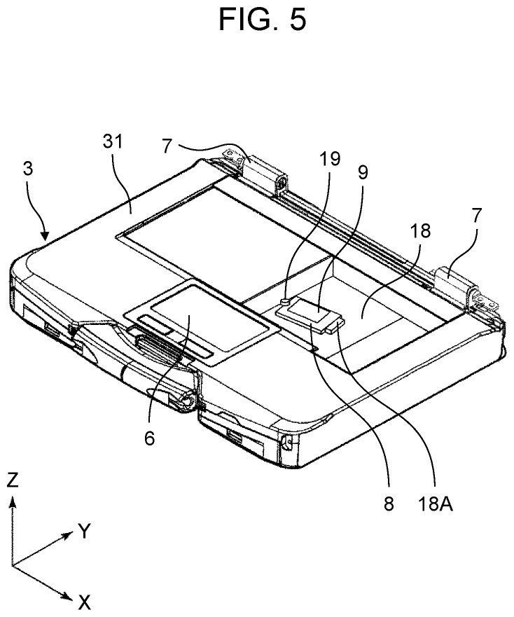

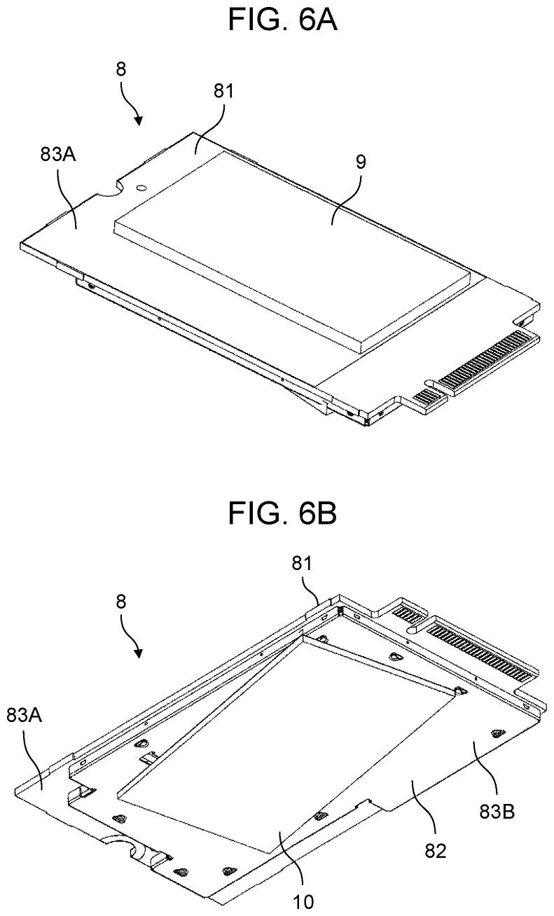

FIG. 5 is a diagram illustrating disposition of communication module 8 with a part of second surface 31 of second housing 3 omitted. FIGS. 6A and 6B are perspective views of communication module 8.

As illustrated in FIG. 5, communication module 8 is accommodated in second housing 3. Communication module 8 is a circuit having a communication function. More specifically, communication module 8 is an integrated circuit for enabling communication with an external device via a network, and performs communication in conformity to a standard such as Wi-Fi, IEEE802.2, IEEE802.3, a 3rd generation mobile communication system (3G), a 4th generation mobile communication system (4G), a 5th generation mobile communication system (5G), or long-term evolution (LTE). The network is a wide area network (WAN), a local area network (LAN), or the like. Communication module 8 performs communication via a wireless WAN in conformity to a standard of 5G using a frequency of 28 GHz or more, for example.

Communication module 8 has first module surface 82 facing first surface 32 and second module surface 81 facing second surface 31 (FIGS. 6A and 6B). Communication module 8 is disposed below keyboard 5 (FIG. 4). As viewed from thickness direction Z, communication module 8 may be covered with keyboard 5. In addition, communication module 8 may be disposed away from an outer periphery of second housing 3. Communication module 8 is disposed, for example, below near a center of keyboard 5.

Communication module 8 is electrically connected to electronic substrate 18. A processor that executes control of electronic device 1 is implemented on electronic substrate 18. Communication module 8 is electrically connected to connector 18A of electronic substrate 18 at one end, and is fixed to electronic substrate 18 at the other end. The other end of communication module 8 is fixed by, for example, screw 19.

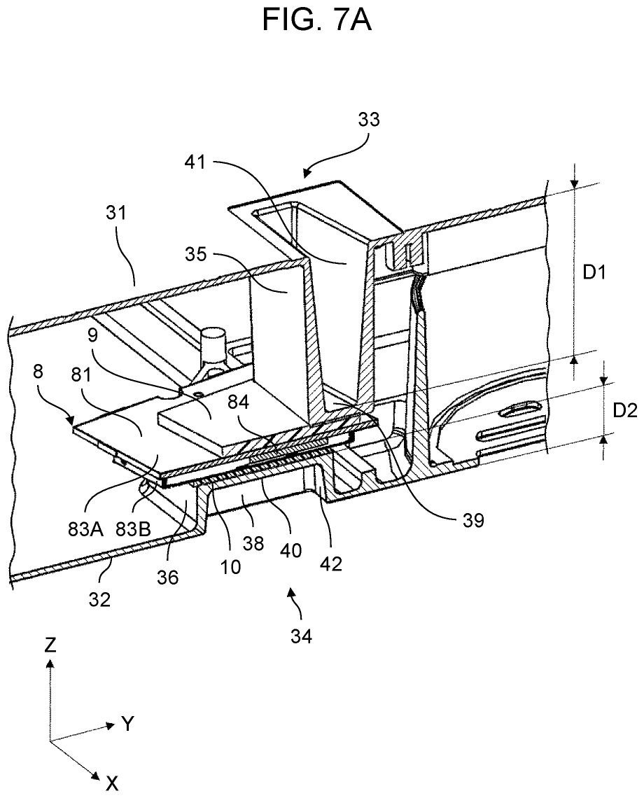

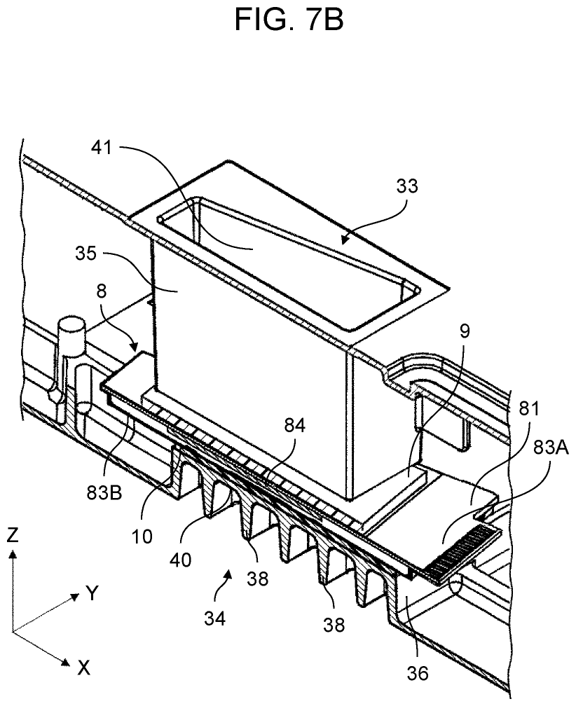

As illustrated in FIGS. 6A and 6B, in the present exemplary embodiment, communication module 8 includes communication module substrate 83A, controller 84 (FIGS. 7A and 7B) implemented on communication module substrate 83A, and case 83B covering controller 84. Communication module substrate 83A forms second module surface 81, and case 83B forms first module surface 82. Controller 84 includes a processor that exhibits a communication function. Controller 84 may include a plurality of electronic components. When communication module 8 operates, controller 84 generates heat. Case 83B may be made of metal, and the heat generated from controller 84 can be diffused throughout case 83B.

### [Heat Dissipation Material]

As illustrated in FIG. 6A, second heat dissipation material 9 is disposed on second module surface 81. As illustrated in FIG. 6B, first heat dissipation material 10 is disposed on first module surface 82.

Heat dissipation materials 9 and 10 are sheet-shaped heat dissipation rubbers having a heat dissipation function. Heat dissipation materials 9 and 10 come into physical contact with first module surface 82 and second module surface 81, respectively. Heat dissipation materials 9 and 10 may be disposed on a part or the entire surface of second module surface 81 and first module surface 82, respectively. Heat dissipation materials 9 and 10 are disposed to sandwich controller 84, for example.

Heat dissipation materials 9 and 10 may contain silicone rubber. For example, heat dissipation materials 9 and 10 are mixed materials of silicone polymers and ceramics. Heat dissipation materials 9 and 10 may be formed of the same material or may have the same thickness and size.

In addition to the heat dissipation function, heat dissipation materials 9 and 10 have a function of alleviating impact when electronic device 1 falls.

Here, a positional relationship between first recess 34, second recess 33, and communication module 8 will be described with reference to FIGS. 7A and 7B.

FIG. 7A is a perspective cross-sectional view of electronic device 1 taken along line A-A illustrated in FIG. 4. FIG. 7B is a perspective cross-sectional view of electronic device 1 taken along line B-B in FIG. 4.

As illustrated in FIGS. 7A and 7B, second recess 33, communication module 8, and first recess 34 are disposed to be lined up in thickness direction Z. The disposition in which second recess 33, communication module 8, and first recess 34 are lined up in thickness direction Z means disposition in which structures thereof partially overlap as viewed from thickness direction Z. For example, second recess 33 may be disposed to be deviated from first recess 34, or first recess 34 and second recess 33 may be disposed to overlap each other on the entire surface.

More specifically, second recess 33, controller 84 of communication module 8, and first recess 34 are disposed to be lined up in thickness direction Z. As viewed in thickness direction Z, controller 84 may be disposed inside first wall 36 that defines first recess 34.

In addition, second wall 35 in second recess 33 has bottom 39 orthogonal to thickness direction Z and side wall 41 extending in thickness direction Z from an outer periphery of bottom 39. First wall 36 in first recess 34 has bottom 40 orthogonal to thickness direction Z and side wall 42 extending in thickness direction Z from an outer periphery of bottom 40. As illustrated in FIGS. 7A and 7B, bottom 40 extends in directions (X-direction and Y-direction) orthogonal to thickness direction Z.

Second wall 35 comes into physical contact with second heat dissipation material 9, and first wall 36 comes into physical contact with first heat dissipation material 10. More specifically, a surface of bottom 39 on first surface 32 side comes into physical contact with second heat dissipation material 9, and a surface of bottom 40 on second surface 31 side comes into physical contact with first heat dissipation material 10. Accordingly, bottoms 39 and 40 come into contact with communication module 8 via heat dissipation materials 9 and 10. In addition, the other surface of bottom 39 and the other surface of bottom 40 come into contact with the outside air.

As viewed in thickness direction Z, bottom 39 may have an area smaller than an area of second heat dissipation material 9 and be disposed inside an outer periphery of second heat dissipation material 9. As viewed in thickness direction Z, bottom 40 may have an area substantially equal to an area of first heat dissipation material 10. In addition, the area of bottom 40 in contact with first heat dissipation material 10 may be larger than the area of bottom 39 in contact with second heat dissipation material 9. With such a structure, heat dissipation through first surface 32 can be preferentially performed. Thus, the heat of electronic device 1 can be released in a direction away from the user.

Bottom 39, second heat dissipation material 9, communication module 8, first heat dissipation material 10, and bottom 40 are disposed to be lined up in thickness direction Z. In other words, communication module 8 is disposed to be sandwiched between bottom 39 and second heat dissipation material 9, and bottom 40 and first heat dissipation material 10.

In addition, as illustrated in FIG. 7A, depth D1 of second recess 33 from an opening to bottom 39 along thickness direction Z is larger than depth D2 of first recess 34 from an opening to bottom 40. With this configuration, even in a case where communication module 8 is replaced or repaired, communication module 8 can be easily removed by accessing communication module 8 from first surface 32 side of second housing 3. In addition, even though communication module 8 is at a position close to first surface 32, the heat dissipation function can be improved by second heat dissipation material 9 and second recess 33.

An opening area of second recess 33 decreases from second surface 31 toward first surface 32. The opening area means an area of the opening in a cross section along an XY plane. With such a structure, second recess 33 can be easily formed by using a mold.

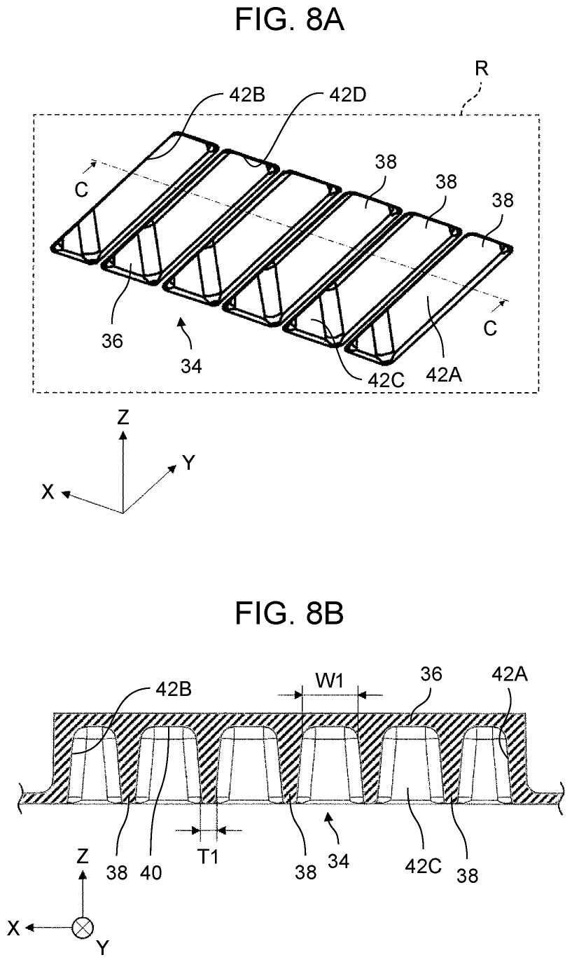

FIG. 8A is an enlarged view of region R in FIG. 3. FIG. 8B is a cross-sectional view of first recess 34 taken along line C-C illustrated in FIG. 8A. As illustrated in FIGS. 8A and 8B, first recess 34 has four side walls 42A to 42D. Side walls 42A and 42B are opposed to each other in the X-direction. Side walls 42C and 42D are opposed to each other in the Y-direction. In addition, side walls 42 are collectively referred to as side walls 42A to 42D. The plurality of fins 38 provided in first recess 34 extend in thickness direction Z from bottom 40, and a surface extending in thickness direction Z comes into contact with the outside air. Fins 38 may be disposed in parallel with each other. Specifically, fins 38 extend from side wall 42C toward side wall 42D between side wall 42A and side wall 42B. Thus, first recess 34 is divided into a plurality of recesses by fins 38.

As illustrated in FIG. 8B, thickness T1 of fin 38 is from 0.5 mm to 2.0 mm inclusive. Thickness T1 of fin 38 is, for example, 1.0 mm. In addition, interval W1 between adjacent fins 38 is from 3.0 mm to 8.00 mm inclusive. Interval W1 between fins 38 is, for example, 5.0 mm. With such a structure, it is possible to suppress clogging of a space between the fins 38 adjacent to each other with foreign matter. In addition, the thickness and the interval of fins 38 may be constant or may change in a tapered shape. When the thickness of fin 38 increases toward second surface 31, first recess 34 can be easily formed by using the mold. In a case where the thickness and the interval of fins 38 change, thickness T1 and interval W1 are minimum values of the thickness and the interval of fins 38, respectively.

Fins 38 may be formed integrally with first wall 36. Fins 38 are formed integrally with first surface 32 of second housing 3, for example.

### [Operation]

In the above-described structure, when communication module 8 generates heat, a temperature gradient is formed between communication module 8 and bottoms 39 and 40. The heat generated in communication module 8 is thermally conducted to bottoms 39 and 40 through heat dissipation materials 9 and 10 along the temperature gradient and is dissipated. More specifically, the heat generated in communication module 8 is diffused to the outside air by heat exchange between bottoms 39 and 40 and the outside air. In addition, fins 38 provided at bottom 40 allow more outside air to be applied to fins 38, and thus, efficiency of heat exchange between fins 38 and the outside air is improved. Thus, more heat can be dissipated from bottom 40.

As a comparative example of first recess 34, the first recess in which fin 38 is not provided was examined. As a result of performing thermal analysis under a condition in which communication module 8 is operating, a maximum temperature in first recess 34 is lower than a maximum temperature in the first recess. Accordingly, the heat dissipation function of electronic device 1 can be improved by providing fins 38 in first recesses 34.

### [Effects]

According to electronic device 1 of the first exemplary embodiment, the following effects can be obtained.

Electronic device 1 of the first exemplary embodiment includes communication module 8, first heat dissipation material 10, keyboard 5, and second housing 3. Communication module 8 has a communication function and has first module surface 82 and second module surface 81 opposed to first module surface 82. First heat dissipation material 10 is disposed on first module surface 82. Keyboard 5 is operated by the user. Second housing 3 accommodates communication module 8 and has first surface 32 facing first module surface 82 and second surface 31 on which keyboard 5 is provided and which is opposed to first surface 32. First recess 34 recessed toward second surface 31 is formed in first surface 32 of second housing 3, and first recess 34 is formed by first wall 36 coming into contact with first heat dissipation material 10.

With such a configuration, the heat dissipation function of communication module 8 is improved by the heat exchange between second housing 3 and first heat dissipation material 10. In addition, first heat dissipation material 10 can be maintained thin by forming first recess 34. Thus, the heat dissipation function of communication module 8 is further improved.

In electronic device 1 of the first exemplary embodiment, the plurality of fins 38 rising in thickness direction Z from second surface 31 toward first surface 32 are provided in first recess 34.

With such a configuration, fins 38 are provided, and thus, it is possible to increase the surface area on which heat exchange with the outside air is performed. Thus, the heat dissipation function of communication module 8 is further improved.

In electronic device 1 of the first exemplary embodiment, first wall 36 has bottom 40 orthogonal to thickness direction Z. Bottom 40 comes into contact with first heat dissipation material 10. The plurality of fins 38 rise in thickness direction Z from bottom 40.

With such a configuration, bottom 40 and first heat dissipation material 10 are brought into contact with each other, and thus, a temperature of bottom 40 approaches a temperature of communication module 8. As a result, a temperature difference from fins 38 can be increased. Accordingly, the heat dissipation function of communication module 8 is further improved.

In electronic device 1 of the first exemplary embodiment, first recess 34 forms a rectangular shape as viewed in thickness direction Z. First wall 36 has two side walls 42 that extend along thickness direction Z and are opposed to each other. The plurality of fins 38 are provided to extend in parallel with each other between two side walls 42 in first recess 34.

With such a configuration, the heat dissipation function of communication module 8 is further improved by increasing the surface area of fins 38 as compared with a case where single fin 38 is provided. In addition, the plurality of fins 38 are disposed to each other, and thus, more fins 38 can be lined up in first recess 34.

In electronic device 1 of the first exemplary embodiment, the plurality of fins 38 are provided at equal intervals.

With such a configuration, air easily enters around fins 38, heat exchange between fins 38 and air is promoted, and the heat dissipation function of communication module 8 is further improved.

Electronic device 1 of the first exemplary embodiment further includes second heat dissipation material 9 disposed on second module surface 81. Second recess 33 recessed toward first surface 32 is formed in second surface 31 of second housing 3, and is formed by second recess 33 is formed by second wall 35 coming into contact with second heat dissipation material 9.

With such a configuration, the heat dissipation function of communication module 8 is further improved by forming second recess 33 and first recess 34 on both surfaces of second housing 3. In addition, second recess 33 and first recess 34 are formed, and thus, it is possible to bring bottoms 39 and 40 into contact with heat dissipation materials 9 and 10 while maintaining the thickness of second housing 3 on first surface 32 and second surface 31 substantially constant. Thus, second housing 3 can be easily manufactured.

In electronic device 1 of the first exemplary embodiment, second recess 33, communication module 8, and first recess 34 are disposed to be lined up in thickness direction Z from second surface 31 toward first surface 32.

With such a configuration, the heat dissipation function of communication module 8 is further improved by sandwiching both surfaces of communication module 8 between second recess 33 and first recess 34.

In electronic device 1 of the first exemplary embodiment, communication module 8 includes controller 84. Second recess 33, controller 84, and first recess 34 are disposed to be lined up in thickness direction Z.

With such a configuration, both surfaces of controller 84 which is a heating element are sandwiched between second recess 33 and first recess 34, and thus, more heat is diffused from controller 84. As a result, the heat dissipation function of communication module 8 is further improved.

In electronic device 1 of the first exemplary embodiment, second recess 33 is covered with keyboard 5.

With such a configuration, the disposition of keyboard 5 can suppress direct transfer of the heat dissipated from communication module 8 through second recess 33 to the user of electronic device 1. In addition, since second recess 33 is positioned below keyboard 5, it is possible to suppress a temperature rise at a position directly touched by the user of electronic device 1.

Electronic device 1 of the first exemplary embodiment further includes lid 37 that covers second recess 33.

With such a configuration, foreign matter, water, or the like flowing into the gap between second housing 3 and keyboard 5 is prevented from flowing into second recess 33.

Note that, in the present exemplary embodiment, an example in which electronic device 1 is a laptop PC has been described, but the present disclosure is not limited thereto. For example, electronic device 1 may be a tablet PC, a smartphone, or another information processing device.

Note that, although an example in which the plurality of fins 38 are provided has been described, the present disclosure is not limited thereto. In addition, fins 38 may not be provided in first recess 34, and one fin 38 may be provided.

Note that, although an example in which fins 38 parallel to each other are provided has been described, the present disclosure is not limited thereto. Fins 38 may be disposed in, for example, a lattice pattern.

Although the present disclosure has been fully described with reference to preferred exemplary embodiments and with reference to the accompanying drawings, various changes and modifications will become apparent to those skilled in the art. Such variations and modifications are to be understood as being included within the scope of the present disclosure as set forth in the appended scope of claims unless departing from the scope of the present disclosure.

Since the present disclosure can improve a heat dissipation function of an electronic device, the present disclosure is applied to, for example, an electronic device (for example, a laptop PC, a tablet PC, or the like).

What is claimed is:

1. An electronic device comprising:
a communication module that includes a communication function, and includes a first module surface and a second module surface opposed to the first module surface;
a first heat dissipation material that is disposed on the first module surface;
an input interface that is operated by a user;
a housing that accommodates the communication module, and includes a first surface facing the first module surface and a second surface opposed to the first surface, the input interface being provided on the second surface, and
wherein the first surface of the housing includes a first recess recessed toward the second surface, and
the first recess includes a first wall coming into contact with the first heat dissipation material.

2. The electronic device according to claim 1, wherein the first recess includes one or a plurality of fins rising in a thickness direction from the second surface toward the first surface.

3. The electronic device according to claim 2,
wherein the first wall includes a bottom extending in a direction orthogonal to the thickness direction,
the bottom comes into contact with the first heat dissipation material, and
the one or plurality of fins rise in the thickness direction from the bottom.

4. The electronic device according to claim 2,
wherein the first recess is provided in a rectangular shape as viewed in the thickness direction,
the first wall includes two side walls that extend along the thickness direction and are opposed to each other, and
the plurality of fins are provided in the first recess to extend in parallel with each other between the two side walls.

5. The electronic device according to claim 4, wherein the plurality of fins are provided at equal intervals.

6. The electronic device according to claim 1, further comprising
a second heat dissipation material that is disposed on the second module surface,
wherein the second surface of the housing includes a second recess recessed toward the first surface, and
the second recess includes a second wall coming into contact with the second heat dissipation material.

7. The electronic device according to claim 6, wherein the second recess, the communication module, and the first recess are lined up in a thickness direction from the second surface toward the first surface.

8. The electronic device according to claim 7,
wherein the communication module includes a controller, and
the second recess, the controller, and the first recess are lined up in the thickness direction.

9. The electronic device according to claim 6, wherein the second recess is covered with the input interface.

10. The electronic device according to claim 6, further comprising a lid that covers the second recess.

11. The electronic device according to claim 10, wherein the lid is covered with the input interface.

12. The electronic device according to claim 6, wherein a depth of the second recess is larger than a depth of the first recess.
